(19) United States
(12) Patent Application Publication
(10) Pub. No.: US 2026/0247807 A1
(43) Pub. Date: Aug. 20, 2026

(54) DISPLAY DEVICE, MANUFACTURING METHOD OF THE DISPLAY DEVICE, AND ELECTRONIC DEVICE

(71) Applicant: Samsung Display Co., LTD., Yongin-si (KR)

(72) Inventors: Min Chul SONG, Yongin-si (KR); Jong Dae LEE, Yongin-si (KR); Jae Suk MOON, Yongin-si (KR); Jun Hyeuk KO, Yongin-si (KR)

(21) Appl. No.: 19/300,112

(22) Filed: Aug. 14, 2025

(30) Foreign Application Priority Data
Feb. 18, 2025 (KR) 10-2025-0021061

(51) Int. Cl. H10K 59/124; H10H 29/01; H10H 29/41; H10K 59/12; H10K 71/16; H10K 102/00

(52) U.S. Cl. CPC H10K 59/124; H10H 29/012; H10H 29/41; H10K 59/1201; H10K 71/166; H10K 2102/351

(57) ABSTRACT

A display device includes a substrate including a first surface and a second surface opposite to the first surface; light emitting devices arranged on the first surface in a display area in a plan view, where the light emitting devices emits light; a metal film arranged on the second surface and overlapping at least a portion of the second surface in the plan view; and an insulating layer arranged over the second surface and covering the metal film, where the metal film includes a non-magnetic material.

This application claims priority to Korean Patent Application No. 10-2025-0021061, filed on Feb. 18, 2025, and all the benefits accruing therefrom under 35 U.S.C. § 119, the content of which in its entirety is herein incorporated by reference.

### BACKGROUND

### (1) Field

Various embodiments of the present disclosure relate to a display device, a manufacturing method of the display device, and an electronic device.

### (2) Description of the Related Art

Display devices are becoming increasingly important with the development of multimedia. In response to this, various types of display devices such as organic light emitting displays (OLEDs) and liquid crystal displays (LCDs) are widely used in various fields.

A display device may include pixels. A light emitting device included in each of the pixels may include electrodes spaced apart from each other and an emission layer arranged between the electrodes. The electrodes and the emission layer may be formed in various ways, and a deposition method of the electrodes or the emission layer may be a method of depositing a deposition material on a surface to be deposited using a mask (e.g., a fine metal mask (FMM)).

### SUMMARY

Embodiments of the present disclosure provide a display device with the improved display quality, a method of manufacturing the display device, and an electronic device. Particularly, embodiments of the present disclosure provide a display device, which is manufactured by a deposition device and can reduce a risk caused by a phenomenon in which a mask is adhered to a substrate during a deposition process, and a method of manufacturing the display device.

A display device according to an embodiment of the present disclosure includes a substrate including a first surface and a second surface opposite to the first surface; light emitting devices arranged on the first surface in a display area in a plan view, where the light emitting devices emit light; a metal film arranged on the second surface and overlapping at least a portion of the second surface in the plan view; and an insulating layer arranged over the second surface and covering the metal film, where the metal film includes a non-magnetic material.

In an embodiment, the metal film may overlap the display area in the plan view.

In an embodiment, the metal film may overlap a non-display area around the display area in the plan view.

In an embodiment, the display area may include emission areas corresponding to the light emitting devices, and the metal film may overlap at least one of the emission areas in the plan view.

In an embodiment, the metal film may have a thickness greater than or equal to about 10 nanometers (nm) and less than or equal to about 10 micrometers (μm).

A method of manufacturing a display device according to another embodiment of the present disclosure includes forming a metal film on a second surface of a substrate; forming an insulating layer over the second surface of the substrate to cover the metal film; forming a backplane structure on a first surface of the substrate, which is opposite to the second surface; arranging the second surface of the substrate adjacent to a magnet assembly; arranging the first surface of the substrate adjacent to a mask; and depositing a deposition material from a deposition source on the first surface of the substrate through the mask.

In an embodiment, the metal film may include a non-magnetic material.

In an embodiment, the metal film may overlap a display area of the display device in a plan view.

In an embodiment, the metal film may overlap a non-display area arranged around a display area of the display device in a plan view.

In an embodiment, regions, in which the deposition material is deposited, may correspond to emission areas of the display device, and the metal film may overlap at least one of the emission areas in a plan view.

In an embodiment, the metal film may have a thickness greater than or equal to about 10 nm and less than or equal to about 10 μm.

In an embodiment, in the arranging the second surface of the substrate adjacent to the magnet assembly, the magnet assembly and the substrate may be arranged adjacent to each other with an electrostatic chuck interposed therebetween.

In an embodiment, the metal film may shield an electric field generated by the electrostatic chuck.

In an embodiment, the magnet assembly may include a yoke plate, and a magnetic field forming portion arranged on the yoke plate, where magnetic field forming portion forms a magnetic field.

In an embodiment, the mask may include a fine metal mask.

In an embodiment, the forming the backplane structure may be performed after the forming the metal film and the forming the insulating layer.

In an embodiment, the forming the backplane structure may be performed before the forming the metal film and the forming the insulating layer.

An electronic device according to another embodiment of the present disclosure includes a processor; and a display device including pixels to display an image under control of the processor. In such an embodiment, the display device includes a substrate including a first surface and a second surface opposite to the first surface; light emitting devices arranged on the first surface in a display area in a plan view, where the light emitting devices emit light; a metal film arranged on the second surface and overlapping at least a portion of the second surface in the plan view; and an insulating layer arranged over the second surface and covering the metal film, where the metal film includes a non-magnetic material.

### BRIEF DESCRIPTION OF THE DRAWINGS

FIG. 1 is a schematic cross-sectional view of a deposition device according to an embodiment of the present disclosure.

FIG. 2 is a diagram illustrating an external force applied to a mask included in the deposition device of FIG. 1 during a deposition process.

FIGS. 3 to 7 are perspective views illustrating an example of a display device which is an object to be subjected to deposition of the deposition device of FIG. 1.

FIG. 8 is a flowchart illustrating a method of manufacturing a display device according to an embodiment of the present disclosure.

FIG. 9 is a flowchart illustrating a method of manufacturing a display device according to another embodiment of the present disclosure.

FIG. 10 is a schematic plan view of a display device manufactured by a method of manufacturing a display device according to embodiments of the present disclosure.

FIG. 11 is a schematic cross-sectional view of a display panel of FIG. 10.

FIG. 12 is a schematic cross-sectional view of a pixel of FIG. 10.

FIG. 13 is a block diagram of an electronic device according to an embodiment of the present disclosure.

FIG. 14 shows schematic diagrams of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. Throughout the specification, in a case where a component is “connected” to another component, the components may be “directly connected” or the components may be “indirectly connected” with another element interposed therebetween.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. “At least one of X, Y, and Z” and “at least one selected from X, Y, and Z” may be interpreted as X only, Y only, Z only, or any combination of two or more of X, Y, and Z (for example, XYZ, XYY, YZ, and ZZ). It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

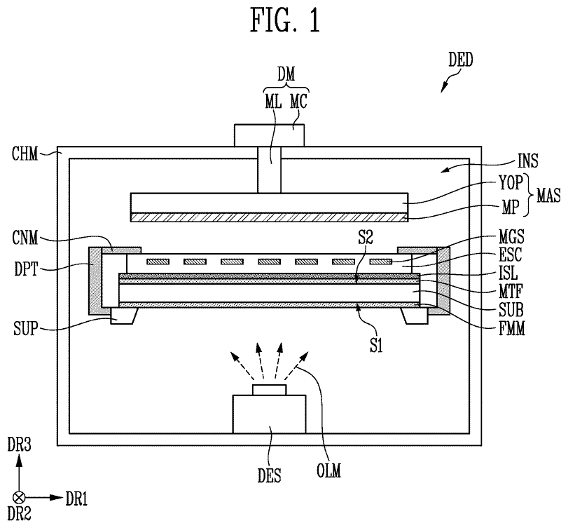

FIG. 1 is a schematic cross-sectional view of a deposition device DED according to an embodiment of the present disclosure.

Referring to FIG. 1, an embodiment of the deposition device DED may include a chamber CHM, a deposition source DES, an electrostatic chuck ESC, and a magnet assembly MAS.

The chamber CHM may provide an internal space INS, and a deposition process may proceed within the internal space INS of the chamber CHM. In an embodiment, for example, a support member SUP, the electrostatic chuck ESC, a driver DPT, a connection member CNM, a yoke plate YOP, a magnetic field forming portion MP, the deposition source DES, and a transfer rod ML of a transfer portion DM may be arranged in the internal space INS of the chamber CHM.

Although not shown in FIG. 1, the chamber CHM may be formed to be at least partially open. According to an embodiment, the opened portion of the chamber CHM may be opened or closed (shielded) through a gate valve or the like.

The deposition source DES may be arranged in the internal space INS of the chamber CHM. The deposition source DES may store a deposition material OLM therein. The deposition source DES may spray the deposition material OLM in a direction toward a mask FMM and a substrate SUB. In an embodiment, for example, the deposition source DES may spray the deposition material OLM including at least one selected from an organic material, an inorganic material, or a conductive material in a direction toward the mask FMM. Although not shown in FIG. 1, the deposition device DED may further include a transfer means (or a moving unit, such as a linear stage, a gantry system, a robotic arm or a rotary/linear combination stage, for example) for moving the deposition source DES in a horizontal direction (e.g., a first direction DR1 or a second direction DR2).

The support member SUP may support and fix the mask FMM. In addition, the support member SUP may raise and lower the mask FMM within a predetermined distance range or rotate the mask FMM within a predetermined angle range.

The mask FMM may be arranged to be fixed on the support member SUP. When the deposition process proceeds, the mask FMM may be adjacent to the substrate SUB. The mask FMM may be arranged between the deposition source DES and the substrate SUB to induce the deposition material OLM to be deposited in desired regions on the substrate SUB. In embodiments, the deposition material OLM deposited on the substrate SUB may be provided as emission layers included in light emitting devices of a display device. Accordingly, regions on the substrate SUB in which the deposition material OLM is deposited may correspond to emission areas of the display device.

In an embodiment, for example, the mask FMM may include a fine metal mask. In addition, the mask FMM may be provided with openings through which the deposition material OLM may pass, and may include a plurality of frames surrounding or defining the openings.

The substrate SUB may be arranged on the mask FMM. The substrate SUB may be a base substrate on which the deposition material OLM is deposited. The substrate SUB may include a first surface S1 and a second surface S2 opposite to the first surface S1. The deposition material OLM may be deposited on the first surface S1 of the substrate SUB through the mask FMM. Accordingly, the deposition material OLM may be deposited in regions overlapping the openings of the mask FMM. Patterns formed of the deposition material OLM may be formed on the first surface S1 of the substrate SUB.

A metal film MTF and an insulating layer ISL may be arranged over the substrate SUB. In an embodiment, for example, the metal film MTF including a non-magnetic material may be arranged on the second surface S2 of the substrate SUB. The insulating layer ISL may cover the metal film MTF on the second surface S2 of the substrate SUB. The insulating layer ISL may be arranged on the metal film MTF. The second surface S2 may be a surface opposite to the first surface S1 of the substrate SUB on which the deposition material OLM is deposited. The metal film MTF and the insulating layer ISL may be arranged between the substrate SUB and the electrostatic chuck ESC.

As the display device to be subjected to the deposition of the deposition device DED becomes larger, the size of the substrate SUB and the mask FMM becomes larger, so a warpage phenomenon of the substrate SUB and the mask FMM may become more severe. In an embodiment, the deposition device DED may include the electrostatic chuck ESC to reduce or mitigate such a warpage phenomenon.

Such an electrostatic chuck ESC may be arranged over the second surface S2 of the substrate SUB. The electrostatic chuck ESC may be arranged between the substrate SUB and the magnet assembly MAS. When the deposition process proceeds, the electrostatic chuck ESC may be coupled to the substrate SUB to align the substrate SUB in a predetermined position and effectively prevent or substantially mitigate the substrate SUB from moving. In addition, the electrostatic chuck ESC may effectively prevent or substantially mitigate gas filled between the electrostatic chuck ESC and the substrate SUB from leaking out and effectively prevent or substantially mitigate the substrate SUB from being lifted by the gas.

The electrostatic chuck ESC may include a plurality of electrodes MGS arranged in the electrostatic chuck ESC. The plurality of electrodes MGS may include at least one first electrode and at least one second electrode. At least one first electrode may have a first polarity, and at least one second electrode may have a second polarity opposite to the first polarity. In an embodiment, for example, the first polarity may be a positive polarity (+) and the second polarity may be a negative polarity (−), but are not limited thereto. In an embodiment, for example, the first polarity may be a negative polarity (−) and the second polarity may be a positive polarity (+).

The driver DPT may drive the electrostatic chuck ESC. In an embodiment, for example, the driver DPT may be connected to the electrostatic chuck ESC through the connection member CNM and drive the electrostatic chuck ESC. In an embodiment, for example, a power source is included in the driver DPT, and the power source of the driver DPT may be electrically connected to the first and second electrodes included in the electrostatic chuck ESC through the connection member CNM.

When the power of the driver DPT is applied to the electrostatic chuck ESC, the electrostatic chuck ESC may form an electric field in the surrounding area of the electrostatic chuck ESC. In an embodiment, for example, by applying a predetermined voltage to the first and second electrodes of the electrostatic chuck ESC through the power of the driver DPT, an electric field may be formed around the electrostatic chuck ESC. Accordingly, the substrate SUB and the mask FMM may be brought into close contact with (or adhered to) each other by the electric field. In an embodiment, for example, the electric field formed by the electrostatic chuck ESC may pull the substrate SUB and the mask FMM in a direction toward the electrostatic chuck ESC (e.g., a third direction DR3). However, when the metal film MTF and the insulating layer ISL are arranged between the substrate SUB and the electrostatic chuck ESC, the electric field formed by the electrostatic chuck ESC might not affect the mask FMM under the substrate SUB. Accordingly, the electric field formed by the electrostatic chuck ESC may pull the metal film MTF, the insulating layer ISL, and the substrate SUB, but may not pull the mask FMM, in the direction toward the electrostatic chuck ESC.

The magnet assembly MAS may be arranged above the second surface S2 of the substrate SUB. The magnet assembly MAS may be arranged to be spaced apart from the second surface S2 of the substrate SUB. The electrostatic chuck ESC may be arranged between the magnet assembly MAS and the substrate SUB. The magnet assembly MAS may be raised or lowered in the third direction DR3. In an embodiment, for example, when the deposition process proceeds, the magnet assembly MAS may move adjacent to the substrate SUB.

The magnet assembly MAS may include the yoke plate YOP and the magnetic field forming portion MP.

The yoke plate YOP may include a plate which induces a path of a magnetic field. In an embodiment, for example, the yoke plate YOP may include a magnetic material including stainless steel or the like. However, embodiments are not limited thereto.

The yoke plate YOP may be arranged on one plane. The plane on which the yoke plate YOP is arranged may be defined based on the first direction DR1 and the second direction DR2. In an embodiment, for example, at least a portion of the yoke plate YOP may extend in the first direction DR1, and at least another portion of the yoke plate YOP may extend in the second direction DR2.

The magnetic field forming portion MP may be arranged on one surface of the yoke plate YOP. In an embodiment, for example, the magnetic field forming portion MP may be arranged on one surface of the yoke plate YOP facing the electrostatic chuck ESC. The magnetic field forming portion MP may be arranged between the yoke plate YOP and the electrostatic chuck ESC. In an embodiment, for example, the magnetic field forming portion MP may include a magnetic material including a permanent magnet, an electric magnet, or the like. However, embodiments are not limited thereto.

The magnet assembly MAS may form a magnetic field. Accordingly, the substrate SUB and the mask FMM may be brought into close contact with (or adhered to) each other by the magnetic field. In an embodiment, for example, the magnetic field formed by the magnet assembly MAS may pull the mask FMM including a metallic material in a direction toward the magnet assembly MAS (e.g., the third direction DR3). Therefore, when the deposition process proceeds, a binding force between the substrate SUB and the mask FMM may be increased, and the sagging of the substrate SUB and the mask FMM may be effectively prevented or substantially mitigated.

The transfer portion DM may be connected to the magnet assembly MAS. The transfer portion DM may include the transfer rod ML and a transfer main body MC. The transfer main body MC may raise or lower the magnet assembly MAS in the third direction DR3 through the transfer rod ML. In addition, the transfer main body MC may rotate the magnet assembly MAS within a predetermined angle range through the transfer rod ML, and may also linearly move in various directions within a predetermined distance range.

The magnet assembly MAS may be arranged to overlap the electrostatic chuck ESC in the third direction DR3. When the magnetic field formed by the magnet assembly MAS and the electric field formed by the electrostatic chuck ESC act on the mask FMM at the same time, the mask FMM and the substrate SUB may be brought into closer contact with each other, but a position of the mask FMM may be changed unintentionally. In an embodiment, for example, when a magnetic force by the magnetic field and an electrostatic force by the electric field act in different directions, or when strengths or directions of these two forces do not match each other, the mask FMM may be aligned differently than desired or intended on the substrate SUB. Accordingly, the relative position of the mask FMM with respect to the substrate SUB may be changed unintentionally.

In an embodiment, to reduce or mitigate such a phenomenon or unintentional change of the position of the mask FMM, the electric field formed by the electrostatic chuck ESC may be shielded by arranging the metal film MTF on the substrate SUB. The mask FMM is arranged on the first surface S1 of the substrate SUB, and the metal film MTF including a non-magnetic material may be arranged on the second surface S2 of the substrate SUB. The metal film MTF arranged on the second surface S2 of the substrate SUB may allow a magnetic field to pass therethrough, but may shield an electric field. Accordingly, the metal film MTF may allow the magnetic field provided by the magnet assembly MAS to pass therethrough and shield the electric field provided by the electrostatic chuck ESC. Therefore, the position of the mask FMM may be controlled by the magnetic field of the magnet assembly MAS without interference from the electric field of the electrostatic chuck ESC, and accordingly, a relative position of the mask FMM with respect to the substrate SUB may be controlled with high reliability.

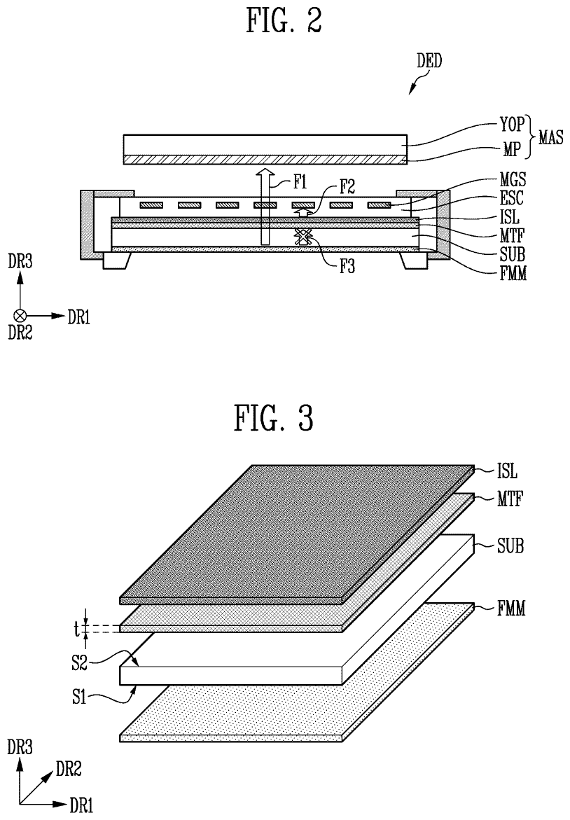

FIG. 2 is a diagram illustrating an external force applied to the mask FMM included in the deposition device DED of FIG. 1 during a deposition process.

Referring to FIGS. 1 and 2, in an embodiment, first to third external forces F1, F2, and F3 may act on the mask FMM and the substrate SUB by the magnet assembly MAS and the electrostatic chuck ESC.

The magnetic field formed by the magnet assembly MAS may act as the first external force F1. The first external force F1 may act on the mask FMM, the substrate SUB, and the electrostatic chuck ESC in the third direction DR3. In an embodiment, for example, the first external force F1 may be a magnetic force capable of pulling the mask FMM including a metallic material in the third direction DR3. In addition, the first external force F1 may be a magnetic force generated between the plurality of electrodes MGS arranged in the electrostatic chuck ESC and the magnet assembly MAS. In an embodiment, the first external force F1 may be the magnetic force formed by aligning magnetic moments of the plurality of electrodes MGS by the magnetic field formed by the magnet assembly MAS.

The electric field formed by the electrostatic chuck ESC may act as the second and third external forces F2 and F3. The second and third external forces F2 and F3 may act on the substrate SUB and the mask FMM in the third direction DR3. In an embodiment, for example, the second and third external forces F2 and F3 may be electrostatic forces capable of pulling the substrate SUB and the mask FMM in the third direction DR3 by an electric field formed by a voltage applied to the electrostatic chuck ESC.

With respect to the substrate SUB and the mask FMM, a direction in which the first external force F1 is applied and a direction in which the second and third external forces F2 and F3 are applied may be the same. Accordingly, when the deposition process proceeds, a binding force between the substrate SUB and the mask FMM may be increased by the first to third external forces F1, F2, and F3, and the sagging of the substrate SUB and the mask FMM may be prevented or mitigated. However, the position of the mask FMM may be changed unintentionally as the magnetic force of the magnet assembly MAS is additionally applied while the mask FMM is in close contact with the substrate SUB by the electrostatic force of the electrostatic chuck ESC. In this case, the alignment of the mask FMM with the substrate SUB may be changed unintentionally.

According to embodiments, the metal film MTF may be arranged between the substrate SUB and the electrostatic chuck ESC. Accordingly, the third external force F3 by the electrostatic chuck ESC may be shielded by the metal film MTF. By arranging the metal film MTF including the non-magnetic material between the substrate SUB and the electrostatic chuck ESC, the first external force F1 by the magnet assembly MAS may pass through the metal film MTF, and the third external force F3, between the second and third external forces F2 and F3 by the electrostatic chuck ESC, may be shielded the metal film MTF. In an embodiment, as described above, by effectively preventing or substantially mitigating the mask FMM from being unintentionally misaligned by the third external force F3, the position of the mask FMM may be controlled with relatively high reliability to increase pixel position accuracy (PPA), thereby improving display quality. This may be more effective in high resolution display devices and/or precision manufacturing processes where pixel accuracy is important. The size, position, and/or design of the metal film MTF may be variously changed or modified, which will be described in detail below with reference to FIGS. 3 to 7.

FIGS. 3 to 7 are perspective views showing embodiments of a display device which is an object to be subjected to deposition of the deposition device DED of FIG. 1.

Referring to FIG. 3, the substrate SUB may include the first surface S1 and the second surface S2 opposite to each other in a thickness direction thereof, or the third direction DR3.

The mask FMM may be arranged on the first surface S1 of the substrate SUB. The mask FMM may pattern the deposition material OLM on the first surface S1 of the substrate SUB. The first surface S1 of the substrate SUB may be a surface on which a light emitting device layer including light emitting devices which emit light is arranged. Although not shown in FIGS. 3 to 7, in a subsequent process, a backplane structure may be arranged on the first surface S1 of the substrate SUB. In an embodiment, for example, the backplane structure may include a thin film transistor for driving pixels, a capacitor, various wires, or the like.

Referring to FIGS. 1 and 3, the metal film MTF may be arranged on the second surface S2 of the substrate SUB. The metal film MTF includes a non-magnetic material and therefore may shield the electric field formed by the electrostatic chuck ESC. In an embodiment, for example, the metal film MTF may overlap the second surface S2 to cover the second surface S2 in whole (i.e., to entirely cover the second surface S2) in a plan view (e.g., viewed from a surface defined by the first direction DR1 and the second direction DR2 or viewed in the third direction DR3). However, embodiments are not limited thereto. In an embodiment, for example, the metal film MTF may overlap at least a portion of the second surface S2 in a plan view.

The metal film MTF may have a thickness t greater than or equal to about 10 nanometers (nm) and less than or equal to about 10 micrometers (μm). In an embodiment, for example, the shielding efficiency (A) of the metal film MTF is determined according to the thickness t of the metal film MTF, so the thickness t of the metal film MTF may be calculated by Equation 1.

$$A = 20 {log}_{10} {e}^{\frac{L}{δ}} \qquad [ Equation 1 ]$$

In Equation 1, L denotes the thickness t of the metal film MTF, and δ denotes a skin depth, which may mean a physical distance at which electromagnetic waves may penetrate into the metal film MTF. δ may be calculated by Equation 2.

$$δ = \sqrt{\frac{2}{{μ}_{1} {ωσ}_{1}}} \qquad [ Equation 2 ]$$

In Equation 2, μ1 denotes magnetic transmittance, ω denotes an angular frequency, and σ1 denotes electrical conductivity.

Accordingly, when the metal film MTF having the thickness t greater than or equal to about 10 nm and less than or equal to about 10 μm is arranged on the second surface S2 of the substrate SUB, the magnetic field formed by the magnet assembly MAS may be passed through the metal film MTF, and only the electric field formed by the electrostatic chuck ESC may be effectively shielded by the metal film MTF. The insulating layer ISL may be arranged on the second surface S2 of the substrate SUB. The insulating layer ISL may be arranged on and cover the metal film MTF. The insulating layer ISL may be arranged on the metal film MTF to electrically insulate and physically protect the metal film MTF. Accordingly, the insulating layer ISL may minimize or reduce the effect of other processes on the metal film MTF and effectively prevent or substantially mitigate electrical problems or mechanical damage which may occur during the process.

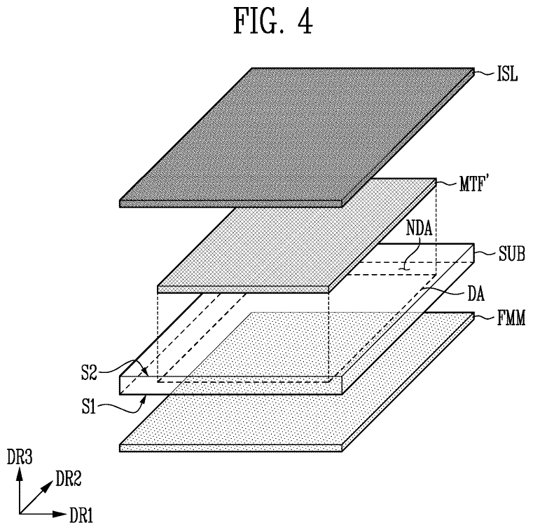

The embodiments shown in FIGS. 4 to 7 is substantially the same as the embodiment shown in FIG. 3 except for the metal film MTF. Hereinafter, any repetitive detailed description of the same or like elements of the embodiments shown in FIG. 4 as those described above will be omitted or simplified, and the embodiments shown in FIGS. 4 to 7 will be described in terms of differences from the embodiment shown in FIG. 3.

Referring to FIGS. 1 and 4, in an embodiment, a metal film MTF′ is arranged on the second surface S2 of the substrate SUB and may overlap a display area DA. In an embodiment, for example, the metal film MTF′ may overlap the display area DA of the substrate SUB in a plan view (e.g., viewed from a plane defined by the first direction DR1 and the second direction DR2). In addition, the metal film MTF′ might not overlap a non-display area NDA of the substrate SUB in a plan view.

In such an embodiment, as the metal film MTF′ is arranged to overlap the display area DA, the effect of shielding the electric field of the electrostatic chuck ESC may be concentrated in the display area DA. Accordingly, the electrostatic interaction between the substrate SUB and the mask FMM arranged on the first surface S1 of the substrate SUB may be reduced, thereby effectively preventing or mitigating unintended changes in the position of the mask FMM.

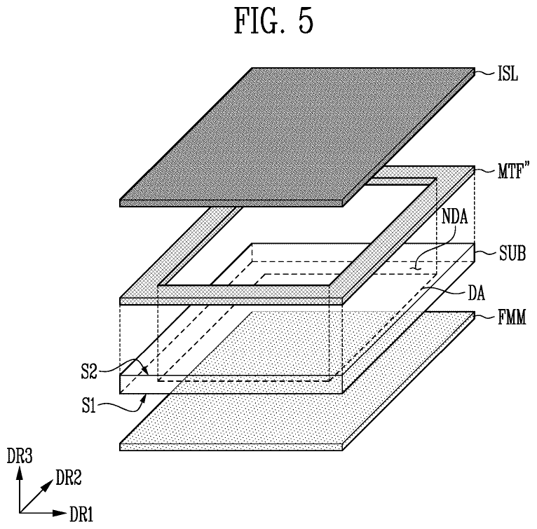

Referring to FIGS. 1 and 5, in another embodiment, a metal film MTF″ may be arranged on the second surface S2 of the substrate SUB and may overlap the non-display area NDA. In an embodiment, for example, the metal film MTF″ may overlap the non-display area NDA of the substrate SUB in a plan view. In addition, the metal film MTF″ might not overlap the display area DA of the substrate SUB in a plan view.

In such an embodiment, as the metal film MTF″ is arranged to overlap the non-display area NDA, the effect of shielding the electric field of the electrostatic chuck ESC may be concentrated in the non-display area NDA. The non-display area NDA is an area where the deposition process has not been carried out, and the effect of shielding the electric field of the metal film MTF″ may be limited. However, the metal film MTF″ overlapping the non-display area NDA may shield the electric field together with existing metal films such as electrodes and a reflective film included in the display area DA. Accordingly, in such an embodiment where the metal film MTF″ is arranged not to overlap the display area DA due to the characteristics of a product, unintended changes in the position of the mask FMM may be effectively prevented or substantially mitigated.

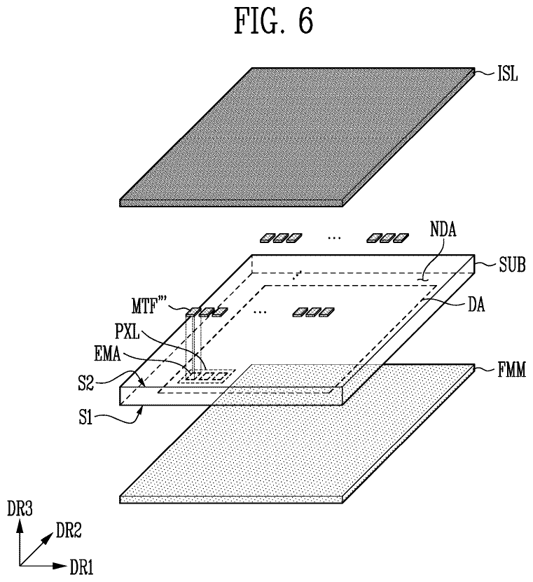

Referring to FIGS. 1 and 6, in another embodiment, metal films MTF′″ may be arranged on the second surface S2 of the substrate SUB and may overlap emission areas EMA included in the display area DA. The emission areas EMA may be areas in which emission layers of light emitting devices are arranged. The metal films MTF′″ may overlap openings of a pixel defining layer which define the emission areas EMA of a pixel PXL.

In such an embodiment, as the metal films MTF′″ overlap at least one of the emission areas EMA, the emission efficiency may be improved along with the effect of shielding the electric field of the electrostatic chuck ESC. In an embodiment, for example, the metal films MTF′″ may be arranged to overlap the emission areas EMA and protect the light emitting device from an external electric field. In addition, the metal films MTF′″ shield the electric field as described above, thereby effectively preventing or mitigating unintended changes in the position of the mask FMM. In addition, the metal films MTF′″ may maintain the consistency of emission with accurate pixel arrangement.

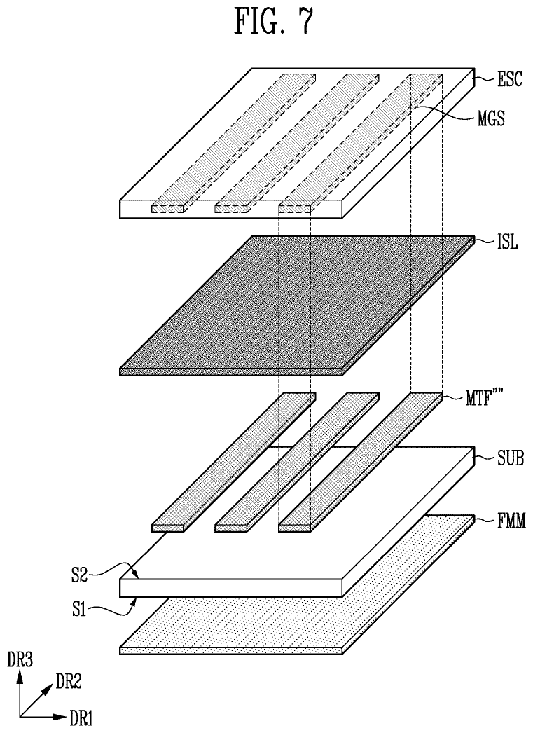

Referring to FIGS. 1 and 7, in another embodiment, metal films MTF″″ may be arranged on the second surface S2 of the substrate SUB and may overlap the plurality of electrodes MGS included in the electrostatic chuck ESC.

In such an embodiment, as the metal films MTF″″ are arranged to overlap the plurality of electrodes MGS of the electrostatic chuck ESC, the metal films MTF″″ may intensively shield the electric field formed in a specific area by the plurality of electrodes MGS of the electrostatic chuck ESC. In an embodiment, for example, the metal films MTF″″ may be arranged to overlap the plurality of electrodes MGS, and may be provided only in an area desired for shielding of the electric field, and may reduce the effect on the emission areas EMA (see FIG. 6).

Hereinafter, an embodiment of a method of manufacturing a display device using the deposition device described with reference to FIGS. 1 to 7 will be described.

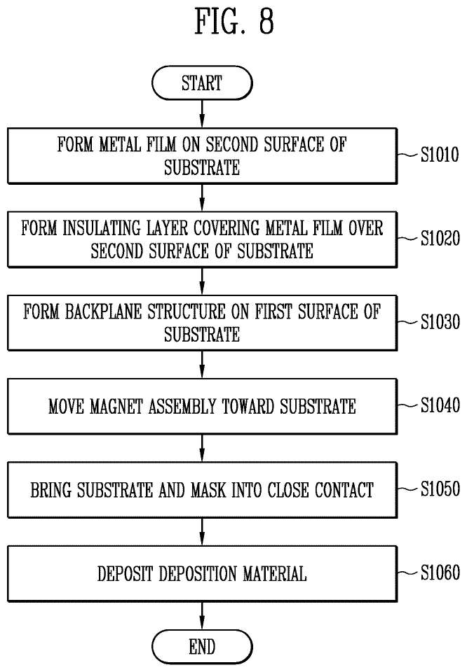

FIG. 8 is a flowchart illustrating a method of manufacturing a display device according to an embodiment of the present disclosure.

Referring to FIGS. 1 and 8, in process S1010, the metal film MTF may be formed on the second surface S2 of the substrate SUB. The substrate SUB may include the opposite first and second surfaces S1 and S2. The first surface S1 of the substrate SUB is a surface on which the deposition material OLM is deposited using the deposition device DED. A pixel circuit layer, a light emitting device layer, an encapsulation layer, or the like may be sequentially stacked over the first surface S1 of the substrate SUB. The pixel circuit layer may be included in a backplane structure. The light emitting device layer may include emission layers of light emitting devices. The encapsulation layer may be arranged on the light emitting device layer. The second surface S2 of the substrate SUB may be a surface facing the electrostatic chuck ESC and the magnet assembly MAS and may be opposite to the first surface S1.

In an embodiment, the metal film MTF may be uniformly formed on the second surface S2 of the substrate SUB. In an embodiment, for example, the metal film MTF may be formed by depositing a non-magnetic material by a physical vapor deposition (PVD) method, a chemical vapor deposition (CVD) method, electroplating, or the like. However, embodiments are not limited thereto. In an embodiment, for example, the metal film MTF may be manufactured separately and may be inserted by an assembly process, a bonding process, or the like.

The metal film MTF formed on the second surface S2 of the substrate SUB may have a thickness greater than or equal to about 10 nm and less than or equal to about 10 μm. In an embodiment, for example, the thickness of the metal film MTF may be adjusted by controlling a deposition rate and a deposition time.

In addition, the metal film MTF may be patterned according to the characteristics and design of the display device. In an embodiment, for example, the metal film MTF may be patterned using dry etching or wet etching. As shown in FIGS. 4 to 7, the metal film MTF may be patterned to overlap at least a portion of the second surface S2 of the substrate SUB. In such an embodiment, the metal film MTF may be patterned and overlap one of a display area, a non-display area, or emission areas. Thereafter, annealing is performed on the metal film MTF, so that the adhesion and mechanical properties of the metal film MTF may be improved.

In process S1020, the insulating layer ISL covering the metal film MTF may be formed on the second surface S2 of the substrate SUB. In an embodiment, for example, the insulating layer ISL may be directly formed on the metal film MTF of the second surface S2 of the substrate SUB. In an embodiment, for example, the insulating layer ISL may be formed by a physical vapor deposition (PVD) method, a chemical vapor deposition (CVD) method, a sol-gel method, or the like. However, embodiments are not limited thereto. The insulating layer ISL may be formed to cover the patterned metal film MTF and include a substantially flat top surface. The insulating layer ISL may protect the patterned metal film MTF, increase the mechanical stability, provide the electrical insulation, and minimize or reduce the impact of other processes on the metal film MTF.

In process S1030, a backplane structure may be formed on the first surface S1 of the substrate SUB. In an embodiment, for example, the backplane structure may be formed on the first surface S1 of the substrate SUB. The backplane structure may be electrical circuits including a thin film transistor for driving a pixel, a capacitor, various wires, or the like.

In process S1040, the magnet assembly MAS may move toward the substrate SUB. The magnet assembly MAS may be moved adjacent to the substrate SUB. In an embodiment, for example, the magnet assembly MAS may be moved adjacent to the substrate SUB and the electrostatic chuck ESC. Accordingly, the magnet assembly MAS and the substrate SUB may be arranged adjacent to each other with the electrostatic chuck ESC interposed therebetween.

In process S1050, the brought into close contact FMM may be brought into close contact. In an embodiment, for example, a strong magnetic field may be formed under the magnet assembly MAS in a state in which the magnet assembly MAS is directly adjacent to the substrate SUB. The magnetic field formed by the magnet assembly MAS may further pull the mask FMM including the metallic material in a direction toward the substrate SUB. Therefore, the substrate SUB and the mask FMM may be brought into close contact with each other by the magnetic field formed by the magnet assembly MAS. In such an embodiment, the electric field formed by the electrostatic chuck ESC is shielded by the metal film MTF arranged between the substrate SUB and the electrostatic chuck ESC, and may not affect the mask FMM under the substrate SUB.

At process S1060, the deposition material OLM may be deposited. The deposition material OLM may be deposited on the first surface S1 of the substrate SUB. By depositing the deposition material OLM, the emission layers of the light emitting device layer may be formed.

The magnetic field formed by the magnet assembly MAS may continuously affect the substrate SUB and the mask FMM. Accordingly, in the deposition process, the mask FMM may be stably in close contact with the first surface S1 of the substrate SUB.

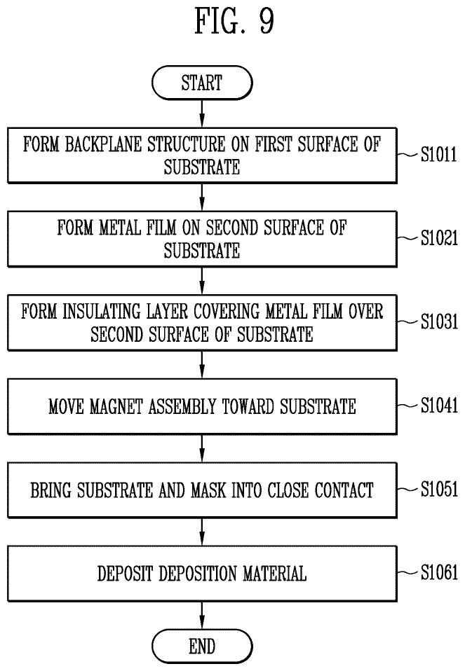

FIG. 9 is a flowchart illustrating a method of manufacturing a display device according to another embodiment of the present disclosure.

Referring to FIGS. 1 and 9, in process S1011, a backplane structure may be formed on the first surface S1 of the substrate SUB. The backplane structure may be formed on the first surface S1 of the substrate SUB patterning the deposition material OLM. The backplane structure may be electrical circuits including a thin film transistor for driving a pixel, a capacitor, various wires, and the like.

In process S1021, the metal film MTF may be formed on the second surface S2 of the substrate SUB. The metal film MTF may be uniformly formed on the second surface S2 of the substrate SUB. In an embodiment, for example, the metal film MTF may be formed by depositing a non-magnetic material by a physical vapor deposition (PVD) method, a chemical vapor deposition (CVD) method, electroplating, or the like.

In process S1031, the insulating layer ISL covering the metal film MTF may be formed on the second surface S2 of the substrate SUB. In an embodiment, for example, the insulating layer ISL may be directly formed on the metal film MTF of the second surface S2 of the substrate SUB. In an embodiment, for example, the insulating layer ISL may be formed by a physical vapor deposition (PVD) method, a chemical vapor deposition (CVD) method, a sol-gel method, or the like. The insulating layer ISL may be formed to cover the patterned metal film MTF and include a substantially flat top surface.

Thereafter, processes S1041, S1051, and S1061 are performed. Descriptions of processes S1041, S1051, and S1061 are similar to those of processes S1040, S1050, and S1060 described with reference to FIG. 8, respectively, and any repetitive detailed description thereof will be omitted.

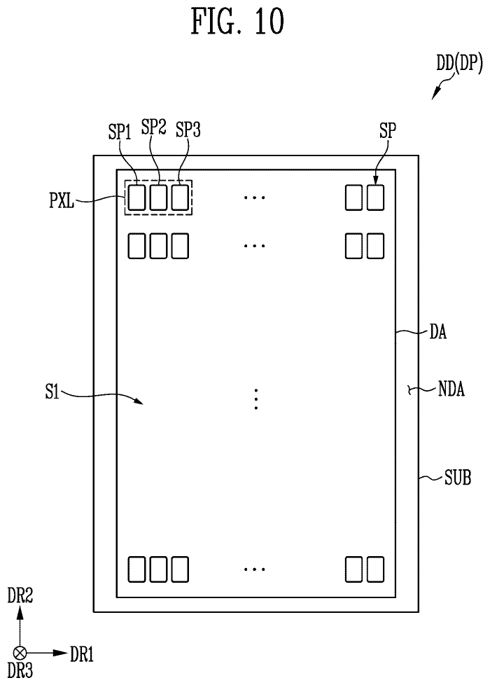

FIG. 10 is a schematic plan view of a display device manufactured by a method of manufacturing a display device according to embodiments of the present disclosure.

In FIG. 10, for convenience of illustration and description, a structure of a display panel DP around the display area DA of the first surface S1 of the substrate SUB, on which an image is displayed, is schematically shown. However, although not shown in FIG. 10, a driving circuit (for example, at least one of a scan driver, a data driver, or an emission driver), wires, and/or pads may be further arranged on the display panel DP.

Referring to FIG. 10, an embodiment of the display device DD may include the display panel DP for displaying an image and the substrate SUB for forming the display panel DP. The display panel DP and the substrate SUB for forming the display panel DP may include the display area DA and the non-display area NDA. The display area DA may constitute a screen on which an image is displayed, and the non-display area NDA may be an area other than the display area DA.

A plurality of sub-pixels SP may be arranged in the display area DA. Two or more sub-pixels among the plurality of sub-pixels SP may constitute one pixel (or one unit pixel) PXL. In an embodiment, for example, one pixel PXL may include a first sub-pixel SP1, a second sub-pixel SP2, and a third sub-pixel SP3, but is not limited thereto. In an embodiment, for example, one pixel PXL may include one first sub-pixel SP1, two second sub-pixels SP2, and one third sub-pixel SP3. In FIG. 10, the first sub-pixel SP1, the second sub-pixel SP2, and the third sub-pixel SP3 included in one pixel PXL are illustrated. It may be understood that the other pixels also include the first sub-pixel SP1, the second sub-pixel SP2, and the third sub-pixel SP3.

Hereinafter, when at least one sub-pixel among the first sub-pixel SP1, the second sub-pixel SP2, and the third sub-pixel SP3 is arbitrarily referred to as the “sub-pixel SP”, or two or more types of sub-pixels are comprehensively referred to as the “sub-pixels SP”.

The sub-pixels SP may be regularly arranged according to a stripe or PENTILE™ arrangement structure. However, the arrangement structure of the sub-pixels SP is not limited thereto, and the sub-pixels SP may be arranged in the display area DA in various structures and/or manners.

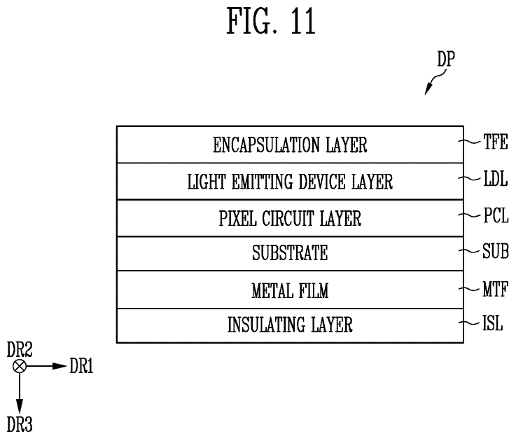

FIG. 11 is a schematic cross-sectional view of the display panel DP of FIG. 10.

Referring to FIG. 11, an embodiment of the display panel DP may include the insulating layer ISL, the metal film MTF, the substrate SUB, a pixel circuit layer PCL, a light emitting device layer LDL, and an encapsulation layer TFE.

The substrate SUB may include a semiconductor substrate. For example, the substrate SUB may include a silicon bulk wafer or an epitaxial wafer. The epitaxial wafer may include a layer of crystalline material, i.e., an epitaxial layer, grown by an epitaxial process on a bulk substrate. The substrate SUB is not limited to a bulk wafer or an epitaxial wafer, and may be formed using various wafers such as a polished wafer, an annealed wafer, or a silicon on insulator (SOI) wafer.

The pixel circuit layer PCL, the light emitting device layer LDL, and the encapsulation layer TFE may be arranged over the first surface S1 of the substrate SUB (see FIG. 1).

The pixel circuit layer PCL is arranged on the substrate SUB and may include a transistor and signal wires connected to the transistor. In an embodiment, for example, the transistor may be in a form in which an active pattern (or a semiconductor pattern), a gate electrode, a source electrode, and a drain electrode are sequentially stacked with an insulating layer interposed therebetween. The semiconductor pattern may include amorphous silicon, polysilicon, low temperature polysilicon, an organic semiconductor, and/or an oxide semiconductor. The gate electrode, the source electrode, and the drain electrode may include at least one selected from aluminum (Al), copper (Cu), titanium (Ti), or molybdenum (Mo), but are not limited thereto. Furthermore, the pixel circuit layer PCL may include at least one insulating layer.

The light emitting device layer LDL may be arranged on the pixel circuit layer PCL. The light emitting device layer LDL may include a light emitting device. The light emitting device is located in each of the sub-pixels SP and may be connected to at least one transistor. According to an embodiment, the light emitting device may include an organic light emitting diode, an inorganic light emitting diode, a quantum dot/well light emitting diode, and the like. However, the embodiments of the present disclosure are not limited thereto.

The encapsulation layer TFE may be arranged on the light emitting device layer LDL. The encapsulation layer TFE may be in the form of an encapsulation substrate or an encapsulation film composed of multiple films. In an embodiment where the encapsulation layer TFE is in the form of the encapsulation film, the encapsulation layer TFE may include an inorganic film and/or an organic film. In an embodiment, for example, the encapsulation layer TFE may have a form in which an inorganic film, an organic film, and an inorganic film are sequentially stacked. The encapsulation layer TFE may prevent or mitigate external air and moisture from penetrating into the light emitting device layer LDL and the pixel circuit layer PCL.

The metal film MTF and the insulating layer ISL may be arranged over the second surface S2 of the substrate SUB (see FIG. 1).

The metal film MTF may be arranged under the substrate SUB and may include a non-magnetic material. The metal film MTF may include a non-magnetic material which has conductive properties but no magnetic properties, thereby capable of shielding the electric field caused by the electrostatic chuck ESC (see FIG. 1). In an embodiment, for example, the metal film MTF may include non-magnetic metals such as silver (Ag), aluminum (Al), gold (Au), copper (Cu), lead (Pb), titanium (Ti), and magnesium (Mg). In another embodiment, for example, the metal film MTF may include a multi-element material including a non-magnetic material such as stainless steel (e.g., 304 stainless steel), an aluminum alloy, a titanium alloy, a magnesium alloy, a copper alloy, or the like. However, an example of a non-magnetic material has been described and is not limited thereto.

The insulating layer ISL may be arranged under the substrate SUB and may cover the metal film MTF. The insulating layer ISL may provide the protection and the electrical insulation of the metal film MTF. In addition, the insulating layer ISL covers the metal film MTF, thereby minimizing or reducing the impact of other processes on the metal film MTF. In an embodiment, for example, the insulating layer ISL may be an inorganic insulating layer including an inorganic material or an organic insulating layer including an organic material.

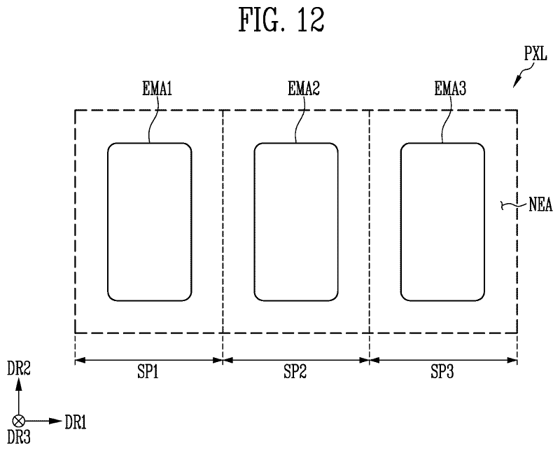

FIG. 12 is a schematic cross-sectional view of the pixel PXL of FIG. 10.

Referring to FIGS. 10 and 12, in an embodiment, one pixel PXL may include the first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

The first emission area EMA1 may be an area in which light is emitted from a light emitting device corresponding to the first sub-pixel SP1. The second emission area EMA2 may be an area in which light is emitted from a light emitting device corresponding to the second sub-pixel SP2. The third emission area EMA3 may be an area in which light is emitted from a light emitting device corresponding to the third sub-pixel SP3. Although not shown in FIG. 12, the respective emission areas EMA 1 to EMA3 may be understood as openings of a pixel defining layer which correspond to the first to third sub-pixels SP1 to SP3, respectively. In an embodiment, for example, the metal film MTF″ (see FIG. 6) may be arranged to overlap at least one of the first to third emission areas EMA 1 to EMA3.

The display device according to an embodiment may be applied to various electronic devices. An electronic device according to an embodiment includes the above-described display device, and may further include a module or device having an additional function other than the display device.

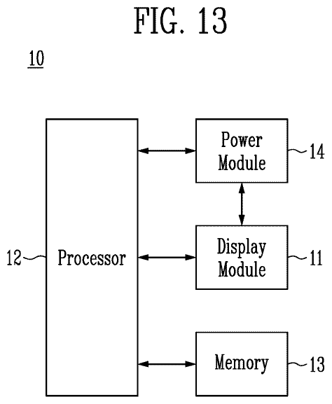

FIG. 13 is a block diagram of an electronic device 10 according to an embodiment of the present disclosure. Referring to FIG. 13, the electronic device 10 according to an embodiment may include a display module 11, a processor 12, memory 13, and a power module 14.

The processor 12 may include at least one selected from a central processing unit (CPU), an application processor (AP), a graphics processing unit (GPU), a communication processor (CP), an image signal processor (ISP), or a controller.

The memory 13 may store data information used for an operation of the processor 12 or the display module 11. When the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module which converts power supplied by the power supply module to generate power used for an operation of the electronic device 10.

At least one of the above-described components of the electronic device 10 may be included in the display device according to the above-described embodiments. In addition, one or more of the individual modules which are functionally included in one module may be included in the display device, and others may be provided separately from the display device. In an embodiment, for example, the display device includes the display module 11, and the processor 12, the memory 13, and the power module 14 may be provided in the form of other devices in the electronic device 10 other than the display device.

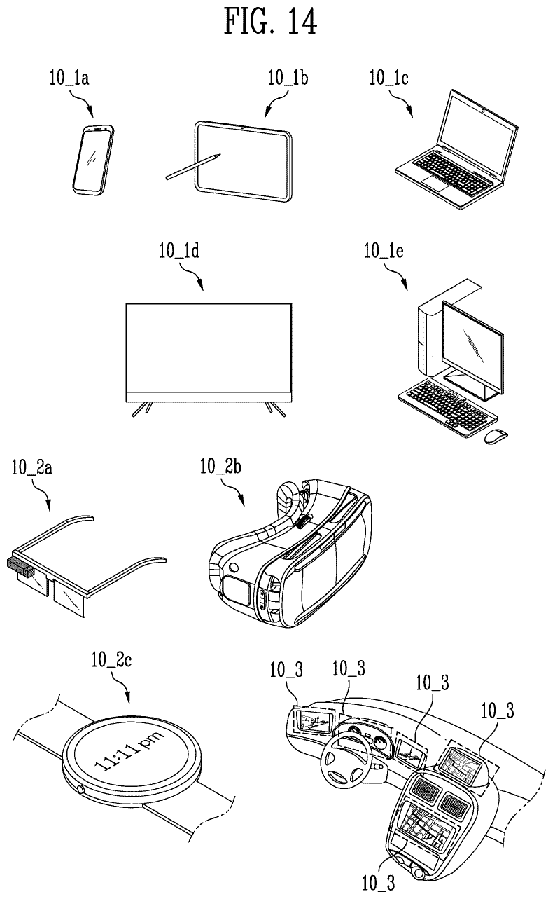

FIG. 14 shows schematic diagrams of an electronic device according to various embodiments.

Referring to FIG. 14, examples of various electronic devices to which a display device according to embodiments of the present disclosure may include electronic devices for displaying images, such as a smartphone 10_1a, a tablet personal computer (PC) 10_1b, a laptop 10_1c, a television 10_1d, or a desk monitor 10_1e, as well as wearable electronic devices including a display module, such as smart glasses 10_2a, a head-mounted display 10_2b, or a smart watch 10_2c, and automotive electronic devices 10_3 including a display module, such as an automotive dashboard, a center fascia, a center information display (CID) placed on a dashboard, or a room mirror display.

The invention should not be construed as being limited to the embodiments set forth herein. Rather, these embodiments are provided so that this disclosure will be thorough and complete and will fully convey the concept of the invention to those skilled in the art.

According to some embodiments of the present disclosure, a display device with the improved display quality, a method of manufacturing the display device may be provided.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a substrate including a first surface and a second surface opposite to the first surface;
light emitting devices arranged on the first surface in a display area, wherein the light emitting devices emit light;
a metal film arranged on the second surface and overlapping at least a portion of the second surface in a plan view; and
an insulating layer arranged over the second surface and covering the metal film,
wherein the metal film includes a non-magnetic material.

2. The display device according to claim 1, wherein the metal film overlaps the display area in the plan view.

3. The display device according to claim 1, wherein the metal film overlaps a non-display area around the display area in the plan view.

4. The display device according to claim 1, wherein the display area includes emission areas corresponding to the light emitting devices, and
wherein the metal film overlaps at least one of the emission areas in the plan view.

5. The display device according to claim 1, wherein the metal film has a thickness greater than or equal to about 10 nm and less than or equal to about 10 μm.

6. A method of manufacturing a display device, the method comprising:
forming a metal film on a second surface of a substrate;
forming an insulating layer over the second surface of the substrate to cover the metal film;
forming a backplane structure on a first surface of the substrate, which is opposite to the second surface;
arranging the second surface of the substrate adjacent to a magnet assembly;
arranging the first surface of the substrate adjacent to a mask; and
depositing a deposition material from a deposition source on the first surface of the substrate through the mask.

7. The method according to claim 6, wherein the metal film includes a non-magnetic material.

8. The method according to claim 6, wherein the metal film overlaps a display area of the display device in a plan view.

9. The method according to claim 6, wherein the metal film overlaps a non-display area arranged around a display area of the display device in a plan view.

10. The method according to claim 6, wherein regions, in which the deposition material is deposited, correspond to emission areas of the display device, and
wherein the metal film overlaps at least one of the emission areas in a plan view.

11. The method according to claim 6, wherein the metal film has a thickness greater than or equal to about 10 nm and less than or equal to about 10 μm.

12. The method according to claim 6, wherein, in the arranging the second surface of the substrate adjacent to the magnet assembly, the magnet assembly and the substrate are arranged adjacent to each other with an electrostatic chuck interposed therebetween.

13. The method according to claim 12, wherein the metal film shields an electric field generated by the electrostatic chuck.

14. The method according to claim 6, wherein the magnet assembly comprises:
a yoke plate; and
a magnetic field forming portion arranged on the yoke plate, wherein magnetic field forming portion forms a magnetic field.

15. The method according to claim 6, wherein the mask includes a fine metal mask.

16. The method according to claim 6, wherein the forming the backplane structure is performed after the forming the metal film and the forming the insulating layer.

17. The method according to claim 6, wherein the forming the backplane structure is performed before the forming the metal film and the forming the insulating layer.

18. An electronic device comprising:
a processor; and
a display device including pixels to display an image under control of the processor,
wherein the display device comprises:
a substrate including a first surface and a second surface opposite to the first surface;
light emitting devices arranged on the first surface in a display area in a plan view, wherein the light emitting devices emit light;
a metal film arranged on the second surface and overlapping at least a portion of the second surface in the plan view; and
an insulating layer arranged over the second surface and covering the metal film, and
wherein the metal film includes a non-magnetic material.
